(19) United States
(12) Patent Application Publication
(10) Pub. No.: US 2025/0006564 A1
(43) Pub. Date: Jan. 2, 2025

(54) SEMICONDUCTOR STRUCTURES WITH COVER LAYERS

(71) Applicant: Taiwan Semiconductor Manufacturing Company, Ltd., Hsinchu (TW)

(72) Inventors: Cheng-Hsiang Wu, New Taipei City (TW); Tsung-Yang Hsieh, Taipei City (TW); Chien-Chang Lee, Hsinchu City (TW); Wen-Tung Chuang, Hsinchu County (TW)

(21) Appl. No.: 18/342,709

(22) Filed: Jun. 27, 2023

(51) Int. Cl. H01L 21/66; H01L 23/00; H01L 25/065

(52) U.S. Cl. CPC H01L 22/32; H01L 24/03; H01L 24/05; H01L 24/16; H01L 25/0657; H01L 2224/02181; H01L 2224/03011; H01L 2224/16145

(57) ABSTRACT

Semiconductor structures, die stack structures, and fabrication methods are provided. In one example, a semiconductor structure includes a die having a test pad disposed on a front side of the die. The test pad has a probe mark in an upper portion of the test pad. The probe mark has an open end at a top surface of the test pad, a bottom wall, a sidewall connected to the bottom wall, and a space between the open end, the bottom wall and the sidewall. The semiconductor structure further includes a first cover layer and a second cover layer. The first cover layer is disposed on the front side of the first test pad and the sidewall and the bottom wall of the probe mark. The second cover layer is disposed on the first cover layer. The first and second cover layers comprise different materials.

### FIELD

Embodiments of the present disclosure relate generally to semiconductor packaging, and more particularly to semiconductor structures and die stack structures.

### BACKGROUND

In recent years, the semiconductor industry has experienced rapid growth due to continuous improvement in integration density of various electronic components, for example, transistors, diodes, resistors, capacitors, etc. Such improvement in integration density is mostly attributed to successive reductions in minimum feature sizes, which allows more components to be integrated into a given area.

These smaller electronic components also require smaller packages that occupy less area than previous packages. Exemplary types of packages for semiconductors include quad flat pack (QFP), pin grid array (PGA), ball grid array (BGA), flip chips (FC), three dimensional integrated circuits (3DICs), wafer level packages (WLPs), and package on package (POP) devices. Some 3DICs are prepared by placing chips over chips on a semiconductor wafer level. 3DICs provide improved integration density and other advantages, such as faster speeds and higher bandwidth, because of the decreased length of interconnects between the stacked chips. However, there are quite a few challenges to be handled for the technology of die stacking and chip packaging.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1F are schematic diagrams illustrating cross-sectional views of intermediate stages in the formation of an example semiconductor structure, in accordance with some embodiments.

FIGS. 2A-2C are schematic diagrams illustrating cross-sectional views of an example method of forming a die stack structure, in accordance with some embodiments.

FIG. 3 is a flow chart diagram illustrating an example method for forming a semiconductor structure and a die stack structure, in accordance with some embodiments.

### DETAILED DESCRIPTION OF THE INVENTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and may not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, source/drain region(s) may refer to a source or a drain, individually or collectively dependent upon the context. For example, a device may include a first source/drain region and a second source/drain region, among other components. The first source/drain region may be a source region, whereas the second source/drain region may be a drain region, or vice versa. One of ordinary skill in the art would recognize many variations, modifications, and alternatives.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Some embodiments of the disclosure are described. Additional operations can be provided before, during, and/or after the stages described in these embodiments. Some of the stages that are described can be replaced or eliminated for different embodiments. Some of the features described below can be replaced or eliminated and additional features can be added for different embodiments. Although some embodiments are discussed with operations performed in a particular order, these operations may be performed in another logical order.

### Overview

When a semiconductor chip or wafer is being tested, probes are used to make contact with the metal pads (i.e., test metal pads or test pads) on the die, and these probes can leave marks, indentations, or scratches on the pads. These probe marks may affect the functionality of the die or cause problems during subsequent chip integration, die stacking, or packaging processes. Particularly, some probe marks may be too deep in shape and size (e.g., with a high aspect ratio), or in a large quantity, and they can lead to reliability issues or failure of the device if not property treated. For example, a cover layer is formed on the test pad prior to die stacking process. The probe mark is filled with the material of the cover layer. The cover layer is usually a high-stress material for protecting the die. However, due to its high stress, the cover layer may lead to incompatibility of the cover layer with the test pad, and the probe mark may induce or initiate voids and cracks of the high-stress cover layer during the die stacking process. For example, when an opening is formed in an area around or proximate to the probe mark, crack of the cover layer or delamination of the cover layer from the test pad can be induced by the probe mark. Accordingly, areas around the probe mark are usually restricted in the die stacking process. For example, other components, such as interconnects or bonding elements, are not placed in close proximity to the probe mark.

The present disclosure provides techniques to address the above-mentioned challenges and/or alleviate the design restrictions caused by probe marks. One insight provided in the present disclosure is related to a novel semiconductor structure (sometimes also referred to as a die structure) having a multi-layer protective structure having multiple cover layers that cover a test pad and fill in the probe mark of the test pad. According to some embodiments, at least two cover layers are sequentially formed to cover the test pad. A first cover layer is formed on the front surface of the semiconductor structure to cover the test pad. The first cover layer may include a low-stress oxide that at least partially fill a portion of the probe mark. A second cover layer is then formed on the first cover layer. According to some embodiments, the probe mark may be entirely or substantially filled with the first cover layer. According to some embodiments, an inner portion of the probe mark is filled with the first cover layer, and an outer portion of the probe mark is filled with the second cover layer. As such, the probe mark may be filled with both a low-stress oxide and a high-stress oxide. The second cover layer may include a high-stress oxide that protects the die and provides mechanical strength to the semiconductor structure. The second cover layer may also provide good step coverage for the probe mark, particularly for the probe mark with a relatively high aspect ratio. The first cover layer could serve as both a buffer layer and a bonding layer to increase the compatibility as well as the bonding strength between the test pad and the second cover layer. Thus, a combination of multiple cover layers (e.g., the first and the second cover layers) could reduce the risk for void, crack, seam, damage, and delamination induced, initiated, or propagated by the probe mark and improve the overall compatibility and mechanical durability of the semiconductor structure during the die stacking process.

According to some embodiments, a third cover layer may be formed on the second cover layer. The third cover layer may be used as an additional protective layer as well as a bonding adhesion layer for the subsequent die stacking process.

Another insighted provided in the present disclosure is related to a die stack structure formed by a first semiconductor structure and a second semiconductor structure bonded through one or more connectors. According to some embodiments, at least one connector (i.e., a bonding structure) interconnects a test pad of the first semiconductor structure and a metal component of the second semiconductor structure. The at least one connector is proximate to a first probe mark. Because of the multiple cover layers that cover the test pad and fill in the probe mark, the overall mechanical durability and performance of the die stack structure can be improved. According to some embodiments, at least one connector interconnects a first test pad of the first semiconductor structure and a second test pad of the second semiconductor structure. The connector is proximate to a first probe mark of the first test pad and a second probe mark of the second test pad that is substantially aligned with the first probe mark in the vertical direction. Because of the multiple cover layers on both the first semiconductor structure and the second semiconductor structure, the overall mechanical durability of the semiconductor structure can be improved, regardless of the proximity of the two probe marks as well as the proximity of the connector to the two probe marks. Therefore, the design restriction due to the probe mark can be alleviated in the die stacking process, and the overall yield and quality of the stacked die package can be improved.

### Example Semiconductor Structures, Die Stack Structures, and Methods

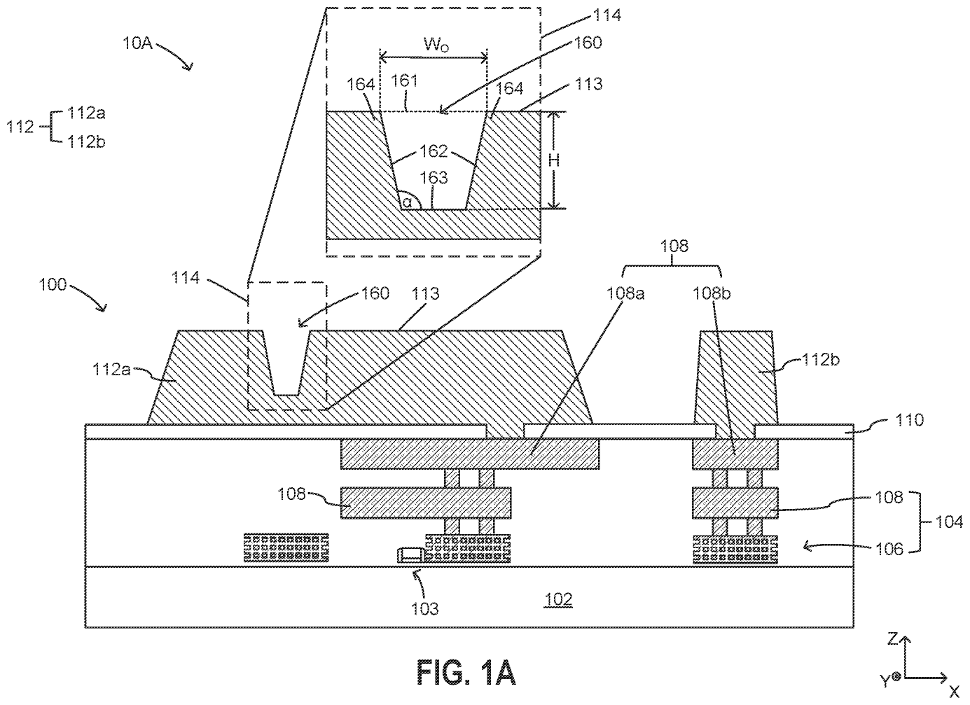

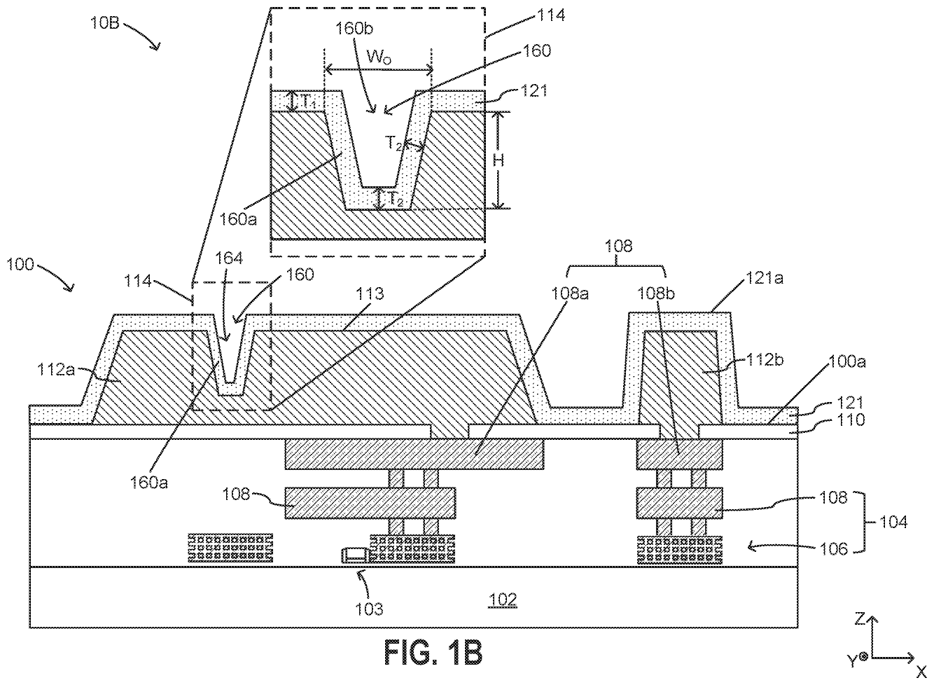

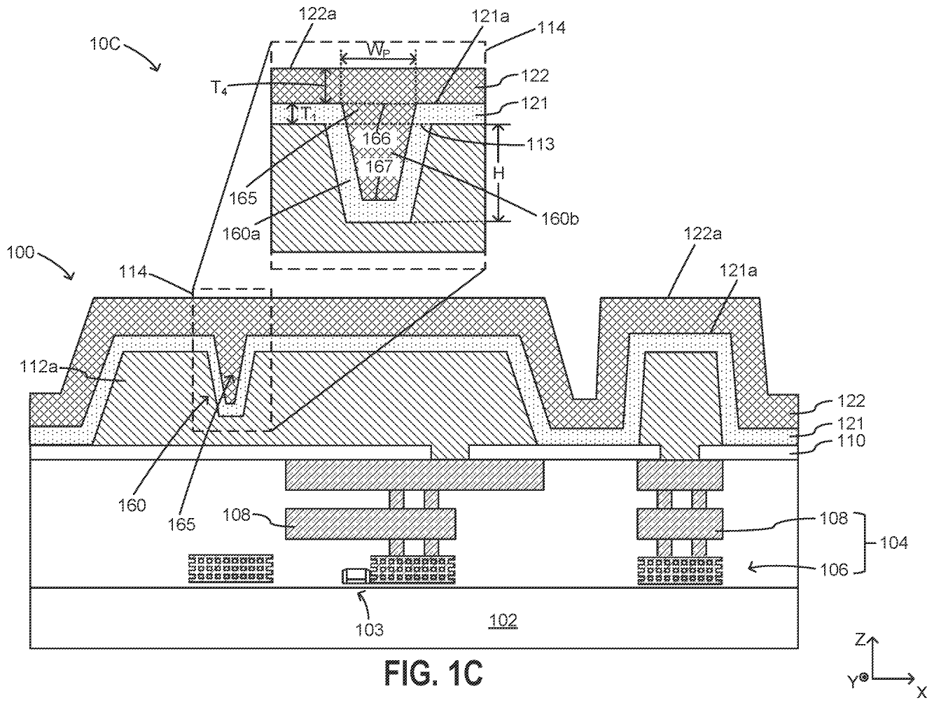

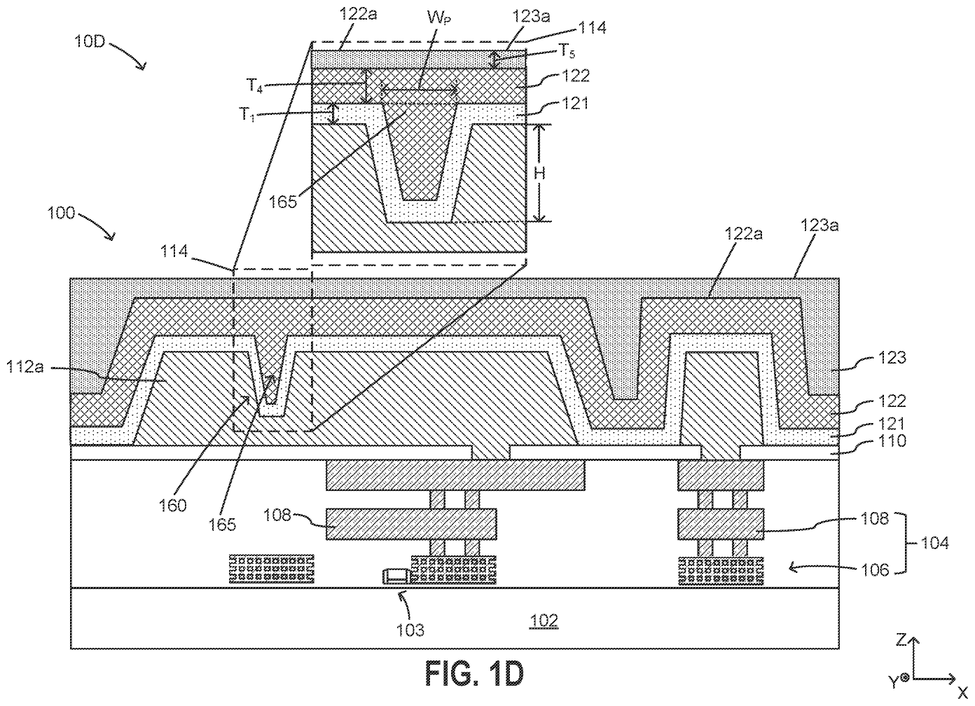

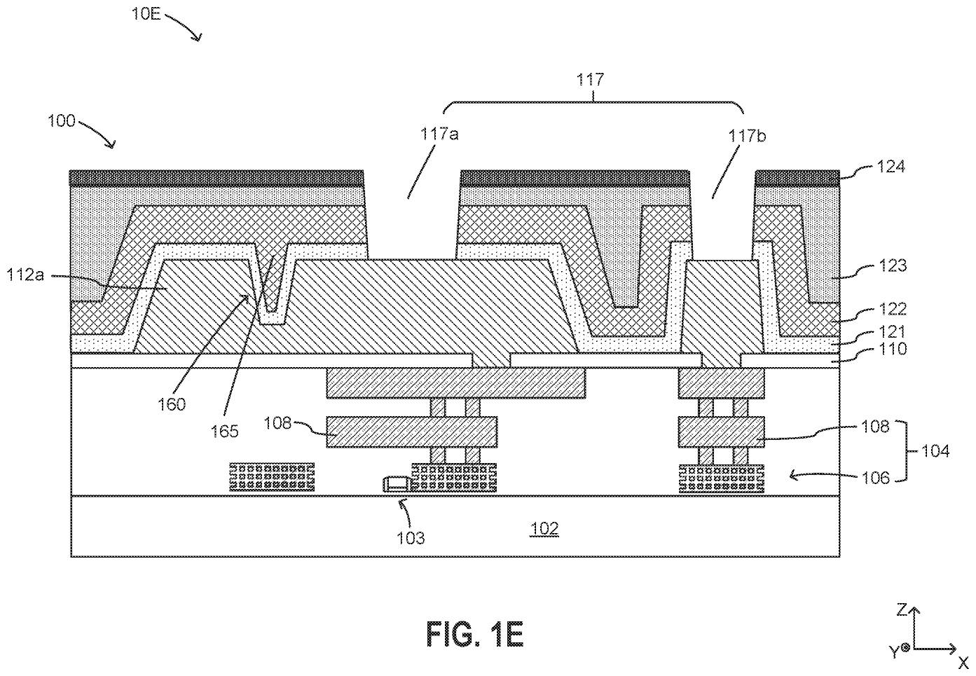

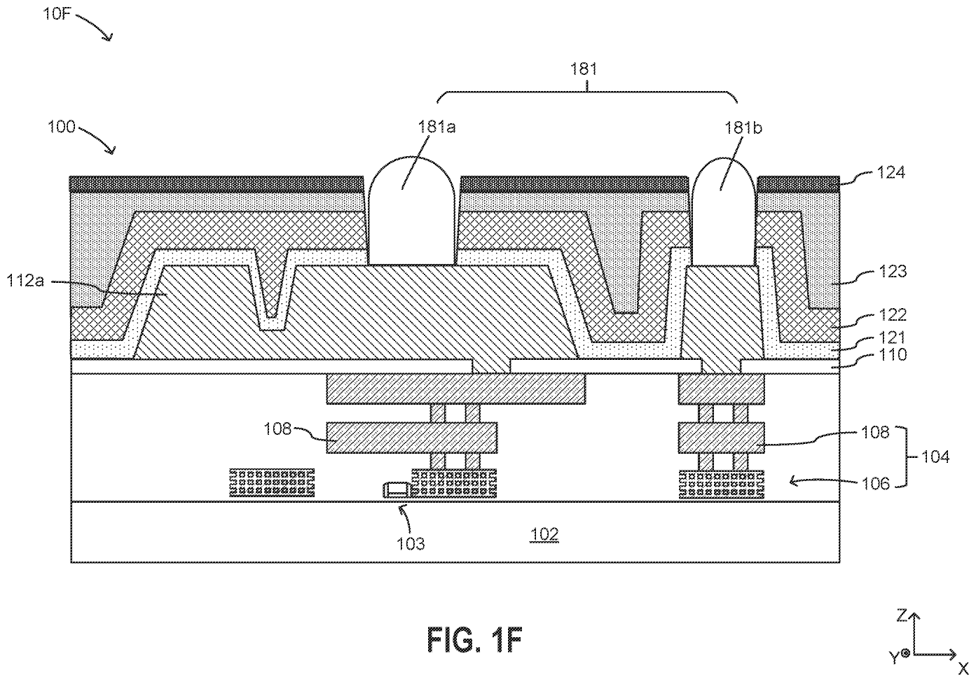

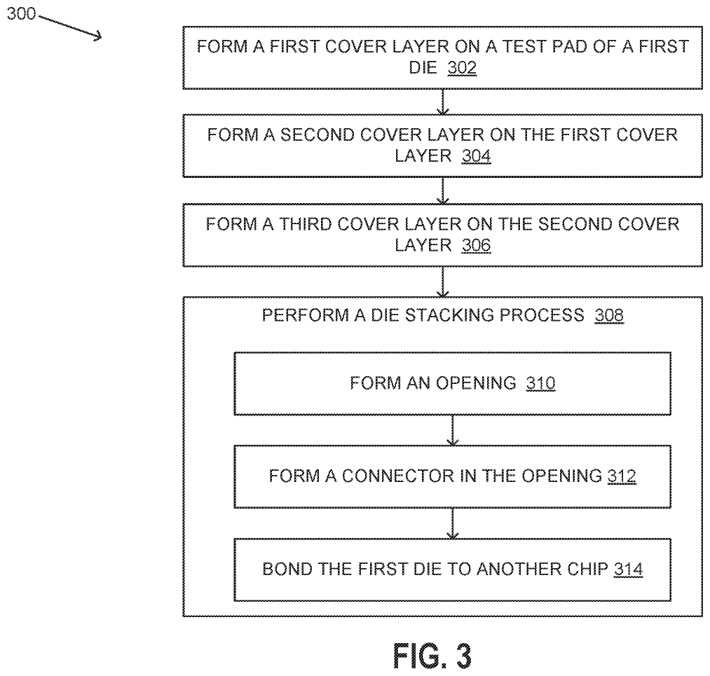

FIGS. 1A-1F are schematic diagrams illustrating cross-sectional views of intermediate stages in the formation of an example semiconductor structure 10F, in accordance with some embodiments. The operations shown in FIGS. 1A-1F are also illustrated schematically in method 300 of FIG. 3. In the subsequent discussion, the operations shown in FIGS. 1A-1F are also discussed referring to the operations in FIG. 3.

As illustrated in an example of a semiconductor structure 10A of FIG. 1A, a first die 100 is provided. The first die 100 serves as a base for the semiconductor structure 10A. The first die 100 may be an application-specific integrated circuit (ASIC) chip, an analog chip, a sensor chip, a wireless and radio frequency chip, a voltage regulator chip or a memory chips, for example. The first die 100 includes, among other components, a first semiconductor substrate 102, a first device region 103, a first interconnect structure 104, a first passivation layer 110, and a first test pad 112.

In some embodiments, the semiconductor substrate 102 may include silicon or other semiconductor materials. Alternatively, or additionally, the first semiconductor substrate 102 may include other elementary semiconductor materials such as germanium. In some embodiments, the first semiconductor substrate 102 is made of a compound semiconductor such as silicon carbide, gallium arsenic, indium arsenide or indium phosphide. In some embodiments, the first semiconductor substrate 102 is made of an alloy semiconductor such as silicon germanium, silicon germanium carbide, gallium arsenic phosphide, or gallium indium phosphide. In some embodiments, the first semiconductor substrate 102 includes an epitaxial layer. For example, the first semiconductor substrate 102 has an epitaxial layer overlying a bulk semiconductor.

In some embodiments, the first device region 103 is formed on the first semiconductor substrate 102 in a front-end-of-line (FEOL) process. The first device region 103 includes a wide variety of devices. In some embodiments, the devices include active components, passive components, or a combination thereof. In some embodiments, the devices may include integrated circuits devices. The devices are, for example, transistors, capacitors, resistors, diodes, photodiodes, fuse devices, or other similar devices. In some embodiments, the first device region 103 includes a gate structure, source/drain regions, and isolation structures, such as shallow trench isolation (STI) structures (not shown). The first device region 103 shown in FIG. 1A are merely examples, and other structures may be formed in the first device region 103. In the first device region 103, various N-type metal-oxide semiconductor (NMOS) and/or P-type metal-oxide semiconductor (PMOS) devices, such as transistors or memories and the like, may be formed and interconnected to perform one or more functions. Other devices, such as capacitors, resistors, diodes, photodiodes, fuses and the like may also be formed on the first semiconductor substrate 102. The functions of the devices may include memory, processors, sensors, amplifiers, power distribution, input/output circuitry, or the like.

As illustrated in FIG. 1A, the first interconnect structure 104 is formed over the first semiconductor substrate 102. The first interconnect structure 104 includes a first insulating material 106 and a plurality of first metal features 108. The first metal features 108 are formed in the first insulating material 106 and electrically connected with each other. A portion of the first metal features 108, such as top metal features 108a and 108b, is exposed by the first insulating material 106. In some embodiments, the first insulating material 106 includes an inner-layer dielectric (ILD) layer on the first semiconductor substrate 102, and at least one inter-metal dielectric (IMD) layer over the inner-layer dielectric layer. In some embodiments, the first insulating material 106 includes silicon oxide, silicon oxynitride, silicon nitride, low dielectric constant (low K) materials or a combination thereof. In some embodiments, the first insulating material 106 may be a single layer or multiple layers. In some embodiments, the first metal features 108 include plugs and metal lines. The plugs may include contacts formed in the ILD layer, and vias formed in the inter-metal dielectric layer. The contacts are formed between and in connect with the substrate 102 and a bottom metal line. The vias are formed between and in connect with two metal lines. The first metal features 108 may be made of tungsten (W), copper (Cu), copper alloys, aluminum (Al), aluminum alloys, or a combination thereof. In some alternatively embodiments, a barrier layer (not shown) may be formed between the first metal features 108 and the first insulating material 106 to prevent the material of the first metal features 108 from migrating to the first device region 103. A material of the barrier layer includes tantalum, tantalum nitride, titanium, titanium nitride, cobalt-tungsten (CoW) or a combination thereof, for example.

As illustrated in FIG. 1A, the first passivation layer 110 is formed over the first interconnect structure 104. The first passivation layer 110 covers the first insulating material 106 and the top metal features 108a. Further, a portion of the top metal features 108b is covered by the first passivation layer 110, and another portion of the top metal features 108b is exposed by the first passivation layer 110, so that another portion of the top metal features 108b may be electrically connected with the to-be-formed one or more first test pads 112 (e.g., first test pads 112a and 112b). In some embodiments, the first passivation layer 110 includes silicon oxide, silicon nitride, benzocyclobutene (BCB) polymer, polyimide (PI), polybenzoxazole (PBO) or a combination thereof and is formed by a suitable process such as spin coating, CVD or the like.

As illustrated in FIG. 1A, the first test pads 112 are formed over the first passivation layer 110 and extends to cover the top metal features 108b. The first test pads 112 have a top surface 113. In some embodiments, a material of the first test pads 112 are different from the material of the first metal features 108. In some embodiments, the material of the first test pads 112 is softer than the material of the first metal features 108. In some embodiments, the first test pads 112 include a metal material, such as aluminum, copper, nickel, gold, silver, tungsten, or a combination thereof. The first test pads 112 may be formed by depositing a metal material layer through a suitable process such as electro-chemical plating process, CVD, atomic layer deposition (ALD), PVD or the like, and then patterning the metal material layer. In some embodiments, the first test pads 112 are in a form of an aluminum pad.

It should be noted that the first die 100 is a known good die (KGD). That is, a die performance test is conducted to the first test pad 112 of the first die 100 to identify or select known good die. In some embodiments, the die performance test is conducted by using a die performance probe (not shown) inserted into at least one of the first test pads 112. As shown in the region 114, a first probe mark 160 is formed at the upper portion of the first test pad 112a after the die performance test is performed. In some embodiments, the first probe mark 160 may be formed over the first passivation layer 110, the top metal features 108b or a combination thereof.

The first probe mark 160 may have various shapes and cross-sectional geometries, including but not limited to, triangle, square, rectangle, trapezoid, and so on. In the example of FIG. 1A the first probe mark 160 has a concave profile and extends from an open end 161 at and aligned with the top surface 113 of the first test pad 112a to a bottom wall 163 in the Z-direction. The probe mark 160 includes a sidewall 162 circumferentially connected to the bottom wall 163. In some embodiments, an angle a formed between the sidewall 162 and the top surface 113 is from 90 to 120 degree. In some embodiments, the bottom wall 163 has a minimum width in the X-direction or is reduced to a point, such that the probe mark 160 has a triangular cross-sectional shape. The probe mark 160 may also be viewed as a space surrounded by the open end 161, the sidewall 162, and the bottom wall 163. For convenience, the probe mark and the space of the probe mark may be used interchangeably in the present disclosure.

The sidewall 162 and the top surface 113 may form a corner portion 164 circumferentially surrounding the open end 161 of the first probe mark 160. In some embodiments, the corner portion 164 protrudes upwardly and is in an elevated position relative to the top surface 113. In some embodiments, a protrusion portion (not shown) of the corner portion 164 may be formed as a result of the material displacement of the first test pad 112 during the formation of the probe mark 160. The protrusion portion may have a shape of raised bump or ring-like configuration surrounding the open end 161 of the probe mark 160.

The probe mark 160 has an opening width (W_{O}) in the X-direction and a height (H) in the Z-direction. The height (H) is characterized by a distance between the top surface 113 and the bottom wall 163. In some embodiments, the width (W_{O}is from 10 μm to 20 μm, from 12 μm to 18 μm, from 14 μm to 16 μm or from 12.5 μm to 15.5 μm. In some embodiments, the height (H) is from 0.2 μm to 1 μm, from 0.4 μm to 0.8 μm, or from 0.5 μm to 0.7 μm. In at least one embodiment, H is about 0.6 μm. The probe mark 160 may have various aspect ratio, characterized by a ratio of H to W_{O}, depending on the probes used and the process of performance testing using the probes. In some embodiments, the probe mark 160 has an aspect ratio (H/W_{O}) from 0.001 to 1,000, from 0.05 to 500, from 0.01 to 100, or from 0.1 to 10.

As illustrated in an example of a semiconductor structure 10B of FIG. 1B, a first cover layer 121 is formed on the first test pads 112. In some embodiments, after the first die 100 is identified as the known good die, the first cover layer 121 is disposed over the top surface 113 of the first test pads 112 as well as a front side 100a of the first die 100 (i.e., the front side of the first passivation layer 110). The first cover layer 121 covers and is in contact with the first test pads 112 and the first passivation layer 110. The first cover layer 121 may be formed by deposition techniques such as CVD, ALD, physical vapor deposition (PVD). In some embodiments, the first cover layer includes a dielectric material such as silicon oxide, silicon nitride, polymer, or a combination thereof. In some embodiments, the first cover layer 121 is a tetraethyl orthosilicate (TEOS) oxide layer formed by TEOS. For example, TEOS may be deposited onto the top surface 113 of the first test pads 112 and the front side of the first die 100, using a CVD process. During the process, TEOS is mixed with oxygen and heated to an elevated temperature, causing it to react and form a layer of silicon dioxide on the top surface 113 of the first test pads 112 and the front side of the first die 100. The TEOS oxide layer may serve as a bonding layer between the first die 100 and additional to-be-formed layers on the first cover layer 121. The TEOS oxide layer may also serve as an insulator between the first die and other to-be-stacked dies in a package structure. The TEOS oxide layer may also serve as a protective layer to protect the first die 100.

Material of the first cover layer 121 may also partially fill an inner portion the probe mark 160 in the first test pad 112a. As illustrated in the expanded view of the region 114 of FIGS. 1A and 1B, the first cover layer 121 is deposited on the top surface 113 of the first test pad 112a, as well as the sidewall 162 and the bottom wall 163 of the probe mark 160. The first cover layer 121 may fill an inner portion 160a (i.e., a first portion) of the probe mark 160 in the first test pad 112a. The inner portion 160a is directly connected to the sidewall 162 and bottom wall 163 of the probe mark 160. The inner portion 160a may be occupied by the first cover layer 121 formed on the sidewall 162 and the bottom wall 163 of the probe mark 160.

In some embodiments, the first cover layer 121 may have a first thickness (T₁) on the top surface 113 of the first test pad 112a, a second thickness (T₂) on the bottom wall 163 of the probe mark 160, and a third thickness (T₃) on the sidewall 162 of the probe mark 160. In some embodiments, the deposition rate of the first cover layer 121 in the deposition process is the same or substantially the same on the on the top surface 113, the sidewall 162, and the bottom wall 163. As a result, T₁, T₂, and T₃ are the same or substantially the same. In some embodiments, the deposition rate of the first cover layer 121 in the deposition process is the same or substantially the same on the on the sidewall 162 and the bottom wall 163 of the probe mark 160. As a result, T₂ and T₃ are the same or substantially the same. In some embodiments, T₁ may be larger than T₂ and T₃. In some embodiments, T₂ and T₃ are smaller or substantially smaller than the height (H) of the probe mark 160. In some embodiments, T₁, T₂, and T₃ are from 0.1 μm to 1 μm, from 0.2 μm to 0.8 μm, or from 0.4 μm to 0.6 μm. In at least one embodiment, T₂ and T₃ are about 0.5 μm.

After the first cover layer 121 is formed, at least a portion of the probe mark 160 is remained unfilled, and the remaining unfilled portion of the probe mark 160 is labeled as an outer portion 160b (i.e., a second portion) of the probe mark 160. The inner and outer portions 160a and 160b may be complementary. The outer portion 160b is spaced from the sidewall 162 and bottom wall 163 of the probe mark 160 by the inner portion 160a. In some embodiments, the inner portion 160a filled with the first cover layer 121 has a total volume of at least 25%, at least 35%, at or least 50%, at least 75%, or at least 95%, based on the total volume of the probe mark 160. In some embodiments, the outer portion 160b that remains unfilled has a volume about 80% or less, about 65% or less, about 50% or less, about 35% or less, about 15% or less, or about 5% or less, based on the total volume of the probe mark 160. In at least one embodiment, the inner portion 160a has a volume of at least 35%, and the outer portion 160b has a volume of 65% or less, based on the total volume of the probe mark 160. A volume ratio of the inner portion 160a to the outer portion 160b is at least 35/65. In at least one embodiment, the entire probe mark 160 is filled with the first cover layer 121.

In some embodiments, the material of the first cover layer 121 is a low-stress oxide film containing a low-stress oxide (LSO). The low-stress oxide may have a stress level from 100 MPa to 200 MPa, from 120 MPa to 180 MPa, or from 135 MPa to 160 MPa. In at least one embodiment, the low-stress oxide may have a stress level about 150 MPa. It should be noted that the stress level of the first cover layer 121 can be controlled, for example, by adjusting the film thickness, selecting appropriate deposition method, tuning deposition parameters, and/or performing a post-treatment.

As illustrated in the example of a semiconductor structure 10C of FIG. 1C, a second cover layer 122 is formed on the first cover layer 121. The second cover layer 122 is deposited onto a front surface 121a of the first cover layer 121 and fill the outer portion 160b of the probe mark 160. The second cover layer 122 may be formed by deposition techniques such as CVD, ALD, plasma-enhanced CVD (PECVD), and PVD. In some embodiments, the second cover layer 122 includes a dielectric material such as silicon oxide, silicon nitride, silicon oxynitride, polymer, or a combination thereof. In some embodiments, the second cover layer 122 is a liner oxide layer. The liner oxide layer may be formed by depositing silicon dioxide onto the first cover layer 121 using a CVD process. The second cover layer 122 may have a front surface 122a and a thickness (T₄) measured by the distance from the front surface 121a of the first cover layer 121 and the front surface 122a of the second cover layer 122 in the Z-direction. In some embodiments, T4 is from 0.1 μm to 5 μm, from 0.2 μm to 4 μm, from 0.4 μm to 3 μm, or from 0.5 μm to 2 μm. In some embodiments, T₄ is larger than T₁. In some embodiments, a ratio of T₄ to T₁ (T₄/T₁) is at least 2, at least 3, or at least 4. In at least one embodiment, T₄/T₁ is at least 2.4.

A protruding structure 165 may be formed after the outer portion 160b of the probe mark 160 is filled with the second cover layer 122. The protruding structure 165 protrudes vertically from a first end 166 horizontally aligned with the front surface 121a to a second end 167 in the probe mark 160. The second end 167 is aligned with a surface of the first cover layer 121 filled in the inner portion 160a of the probe mark 160. The protruding structure 165 has a bottom width (W_{P}). In some embodiments, W_{P} is less than W_{O} and is from 12 μm to 18 μm, from 13 μm to 17 μm, from 13.5 μm to 15.5 μm, or from 14 μm to 15 μm. The outer portion 160b of the probe mark 160 is filled with a portion of the protruding structure 165 (e.g., from the top surface 113 of the first test pad 112a to the second end 167). The protruding structure 165 may have a profile substantially similar to the profile of the probe mark 160. For example, if the probe mark 160 has a triangular cross-sectional shape, the protruding structure 165 may similarly have a triangular cross-sectional shape. The protruding structure 165 is composed of the same material of the second cover layer 122. In some embodiments, the protruding structure 165 may not extend into the probe mark 160, if the probe mark 160 is filled entirely or substantially with the first cover layer 121.

In some embodiments, the second cover layer 122 is a high-stress oxide film and includes a high-stress oxide (HSO) material. In at least one embodiment, the second cover layer 122 has a larger stress level compared with the first cover layer 121. The high-stress oxide material may have a stress level of at least 150 MPa, at least 175 MPa, or at least 200 MPa. In some embodiments, the high-stress oxide material may have a stress level from 150 MPa to 400 MPa, from 175 MPa to 300 MPa, or from 180 MPa to 220 MPa. In at least one embodiment, the first cover layer 121 has a first stress level, the second cover layer 122 has a second stress level, and the second stress level is more than the first stress level, by at least 15 MPa, at least 35 MPa, at least 50 MPa, or at least 70 MPa.

After the second cover layer 122 is formed, the probe mark 160 is filled with a first material (i.e., a low-stress material) derived from the first cover layer 121 in the inner portion 160a and a second material (i.e., a high-stress material) derived from the second cover layer 122 in the outer portion 160b. In some embodiments, the inner portion 160a filled with the first material has a total volume of at least 25%, at least 35%, at least 50%, at least 75%, or at least 95%, based on the total volume of the probe mark 160. In some embodiments, the outer portion 160b filled with the second material has a volume about 80% or less, about 65% or less, about 50% or less, about 35% or less, about 15% or less, or about 5% or less, based on the total volume of the probe mark 160. In at least one embodiment, the inner portion 160a filled with the first material has a volume of at least 35%, and the outer portion 160b filled with the second material has a volume of 65% or less, based on the total volume of the probe mark 160. The first cover layer 121, due to its relatively low stress level, may serve as both a bonding layer and a buffer layer between the first test pad 112a and the second cover layer 122, improve the compatibility and bonding strength between the first and second cover layers 121 and 122, reduce the risk for void, crack, damage formed in the first and second cover layers 121 and 122 proximate to and/or induced by the probe mark 160, reduce the risk for seam or delamination between the first and second cover layers 121 and 122, and improve the overall mechanical durability of the first die 100 in the to-be-formed die stack.

As illustrated in an example of a semiconductor structure 10D of FIG. 1D, a third cover layer 123 is formed on the second cover layer 122. The third cover layer 123 is deposited onto the front surface 122a of the second cover layer 122. The third cover layer 122 may be formed by deposition techniques such as spin coating, CVD, ALD, or PVD, and then performing a planarization process on the third cover layer 123. In some embodiments, the planarization process includes a chemical-mechanical polishing (CMP) process, an etching back process, or a combination thereof. In some embodiments, the third cover layer 123 includes a dielectric material such as silicon oxide, silicon nitride, silicon oxynitride, polymer, or a combination thereof. In some embodiments, the third cover layer 123 includes a low-stress material such as LSO. In some embodiments, the third cover layer 123 includes a material the same or substantially the same as the material of the first cover layer 121. The third cover layer 123 may serve as a bonding layer to a bonding layer of another die in the subsequent die stacking process. The third cover layer 123 may also serve as a blocking layer that blankly cover the second cover layer 122 and further protect the first die 100.

The third cover layer 123 may have a front surface 123a and a thickness (T₅) measured by the distance from the front surface 122a of the first cover layer 122 and the front surface 123a of the third cover layer 123 in the Z-direction. In some embodiments, T₅ is from 0.1 μm to 1 μm, from 0.2 μm to 0.8 μm, or from 0.4 μm to 0.6 μm. In at least one embodiment, T₂ and T₃ are about 0.5 μm. In some embodiments, T₅ is the same of substantially the same as T₁. In some embodiments, T₄ is larger than T₅. In some embodiments, a ratio of T₄ to T₅ (T₄/T₅) is at least 2, at least 3, or at least 4. In at least one embodiment, T₄/T₅ is at least 2.4.

As illustrated in an example of a semiconductor structure 10E of FIG. 1E, one or more openings 117 (e.g., a first opening 117a and a second opening 117b) are formed. Each of the openings 117 is configured to receive and accommodate a conductive element for connection with another die in a subsequent die stacking process. In some embodiments, one or more bonding layers 124 may be formed on the third cover layer, before the openings 117 are formed. The additional bonding layers 124 may be used to facilitate or promote the bonding and adhesion strength between the first die 100 and the other die to-be-bonded to the first die 100. It should be noted that the bonding layer 124 is optional. In some embodiments, no additional bonding layer is formed on the third cover layer 123 prior to die bonding or stacking. In some embodiments, the openings 117a and 117b may extend from a front surface of the bonding layer 124 to the first test pads 112a and 112b, respectively. The openings 117 may be formed by a patterning and etching process, and the position, shape, and dimension of the openings may be controlled by adjusting parameters, depending on design requirements. For example, the opening 117a may be positioned above the probe mark 160 (i.e., aligned or substantially aligned with the probe mark 160).

In some embodiments, at least one opening 117 (e.g., the opening 117a) is proximate to the probe mark 160 of the first test pad 112a. As explained above, the multiple cover layers 121 and 122 with a combination of a low-stress oxide and a high-stress oxide filled in the probe mark 160 of the first test pad 112a effectively reduces the risk for void, crack, damage, seam, and delamination of the cover layers induced by the probe mark 160. In other words, the probe mark may not be a design restriction when selecting the position of the openings for connectors in a die bonding and stacking process.

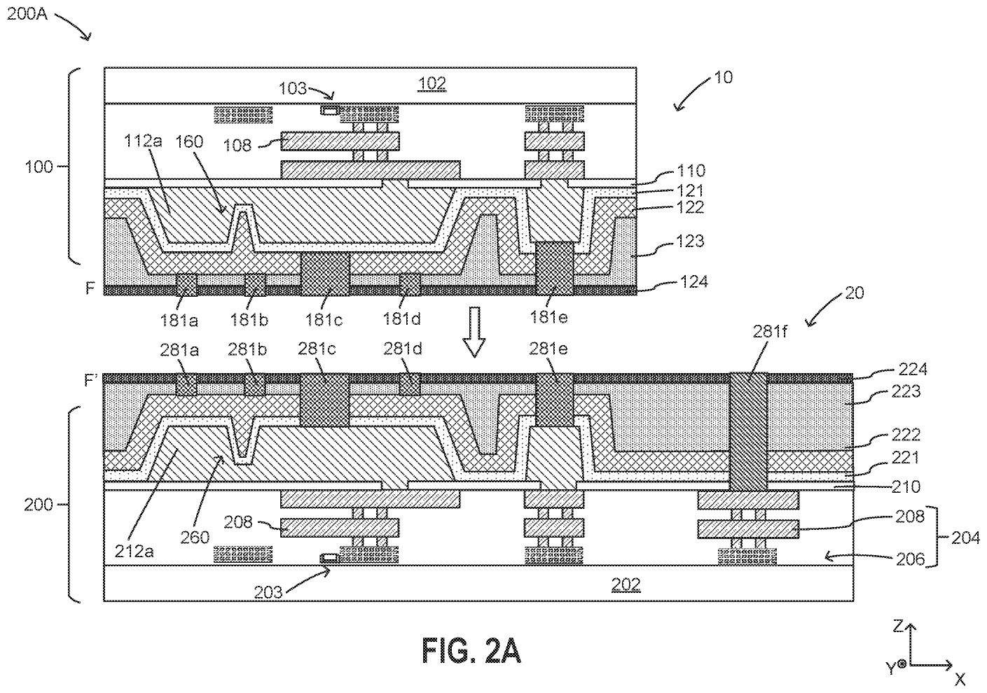

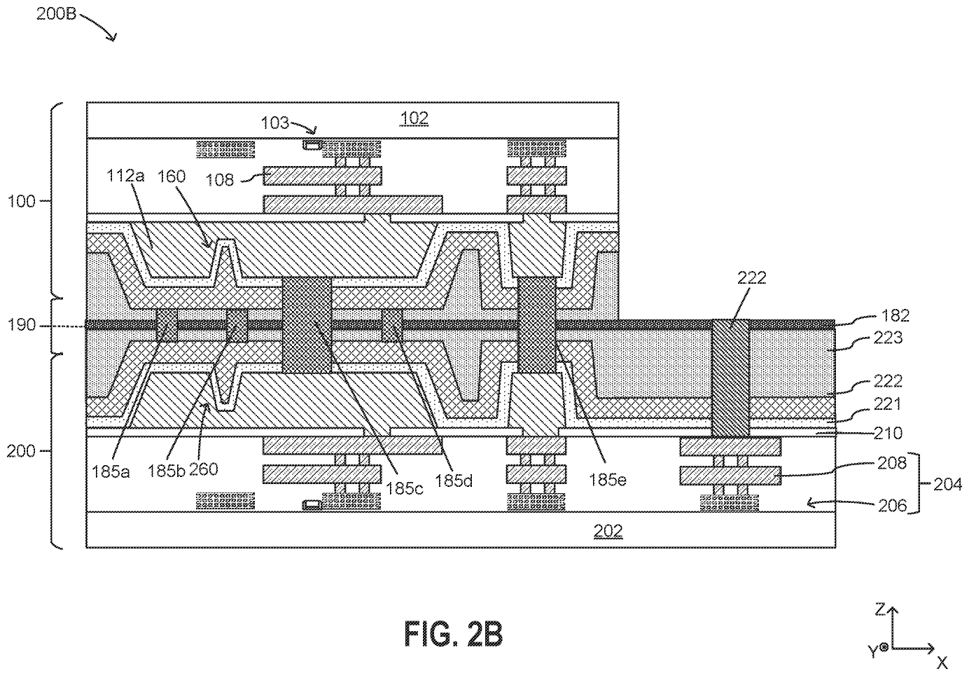

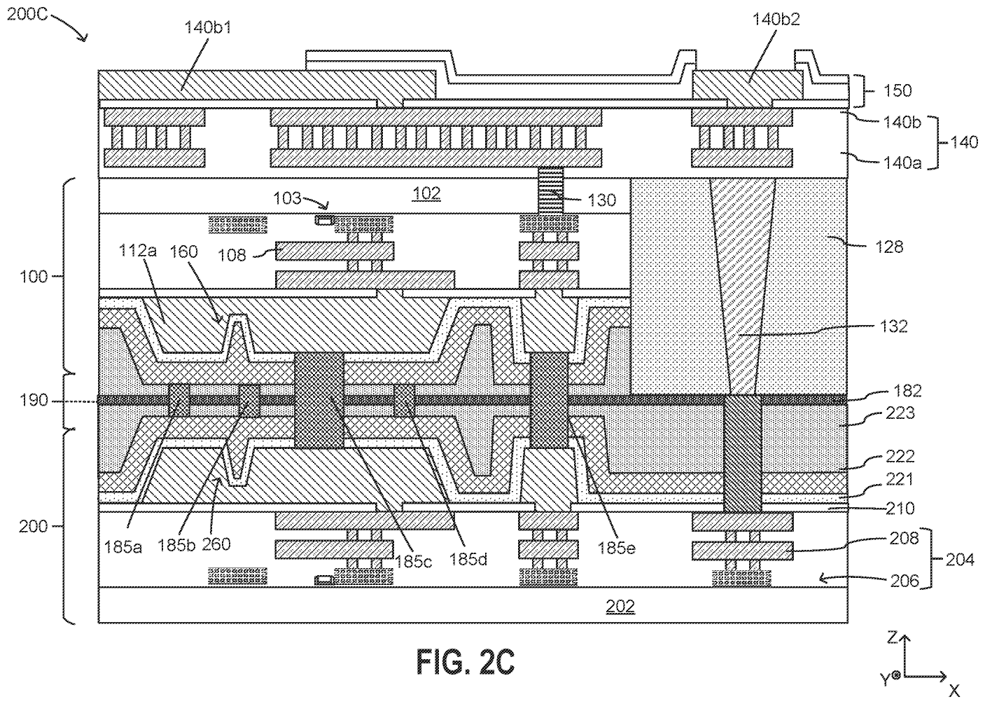

As illustrated in an example of a semiconductor structure 10F of FIG. 1F, one or more connectors 181 are formed. The connectors 181 (e.g., connectors 181a and 181b) may be composed of a conductive element, for example, C4 bumps or micro-bumps. In some embodiments, the connectors 181 may be a conductive assembly including a metal bonding pad connected to a metal contact. The metal bonding pad may be connected to the metal bonding pad of another die to-be-stacked onto the first die through metal-to-metal bonding, fusing bonding, or hybrid bonding. The metal contact may interconnect the metal pad of the conductive assembly with the first test pad 112a of the first die 100. Other types of conductive elements are also possible within the scope of the present disclosure. The semiconductor structure 10F may be used to bond the first die 100 to another die in a die stacking process to form a die stack structure (e.g., the die stack structure 200B of FIG. 2B).

FIGS. 2A-2C are cross-sectional views of a method of forming a die stack structure in accordance with some embodiments. The operations shown in FIGS. 2A-2C are also illustrated schematically in method 300 of FIG. 3. In the subsequent discussion, the operations shown in FIGS. 2A-2C are also discussed referring to the operations in FIG. 3.

As illustrated in an example of a to-be-formed die stack structure 200A of FIG. 2A, a first semiconductor structure 10 and a second semiconductor structure 20 are provided. The first semiconductor structure 10 is based on and includes a first die 100, and the second semiconductor structure 20 is based on and includes a second die 200. The first semiconductor structure 10 is similar to the example semiconductor structure shown in FIGS. 1A-1F. The second die 200 may be an application-specific integrated circuit (ASIC) chip, an analog chip, a sensor chip, a wireless and radio frequency chip, a voltage regulator chip, or a memory chips, for example. The second die 200 and the first die 100 may be the same types of dies or different types of dies. In some embodiments, the second die 200 may be an active component or a passive component.

In some embodiments, the second semiconductor structure 20 is similar to the first semiconductor structure 10. That is, the second semiconductor 200 includes a second semiconductor substrate 202, a second device region 203, a second interconnect structure 204 (including a first insulating material 206 and a plurality of first metal features 208), a second passivation layer 210, and one or more second test pads 212. Like the first die 100, at least one of the second test pads 212 (e.g., the second test pad 212a) includes a probe mark 260 in an upper portion thereof. The arrangement, material and forming method of the second die 200 are similar to the arrangement, material and forming method of the first die 100. Thus, details thereof are omitted here. A difference therebetween lies in that the size of the second die 200 is greater than the size of the first die 100. Herein, the term “size” is referred to the length, width, or area. For example, as shown in FIG. 2A, the length of the second die 200 is greater than the length of the first die 100. For convenience, the probe mark 160 of the first semiconductor structure 10 is labeled as the first probe mark, and the probe mark 260 of the second semiconductor structure 20 is labeled as the second probe mark.

Similar to the first semiconductor structure 10, the second semiconductor structure 20 may be formed by sequentially forming multiple cover layers 221, 222, and 223 onto the front side of the second die 200. Accordingly, the second probe mark 260 is similarly filled with a first material derived from the first cover layer 221 in an inner portion as well as the second material derived from a second material derived from the second cover layer 222 in an outer portion. Similar to the first die 100, the first material filled in the inner portion of the second probe mark 260 may be a low-stress oxide, and the second material filled in the outer portion of the second probe mark 260 may be a high-stress oxide.

It should be noted that the bonding layer 124 of the first semiconductor structure 10 and the bonding layer 224 of the second semiconductor structure 20 are optional. In some embodiments, no additional bonding layers are formed on the third cover layer 123 of the first semiconductor structure 10 and the third cover layer 223 of the second semiconductor structure 20. The third cover layers 123 and 223 may be directly used as bonding layers to bond the first and second dies 100 and 200 together in the die stacking process.

In the illustrated example of FIG. 2A, the first semiconductor structure 10 further includes multiple connectors 181 (e.g., connectors 181a, 181b, 181c, 181d, and 181e) disposed on a front side (F) of the first semiconductor structure 10. As described above, the connectors may be formed by forming corresponding openings on the front side, depositing a conductive element in the openings, and then performing a polarization process to polarize the surface. At least one connector 181 (e.g., the connectors 181a, 181b, and 181c) is proximate to the first probe mark 160, and at least one connector 181 (e.g., the connector 181c) extends through the bonding layer 124 as well as the multiple cover layers 121, 122, and 123 and is in contact with the first test pad 112a. Similarly, the second semiconductor structure 20 further includes multiple connectors 281 (e.g., connectors 281a, 281b, 281c, 281d, 281e, and 281f) disposed on a front side (F′) of the second semiconductor structure 20. At least one connector 281 (e.g., the connector 281c) is proximate to the second probe mark 260, extending through the bonding layer 224 as well as the multiple cover layers 221, 222, and 223, and is in contact with the second test pad 212a. The connectors 281a, 281b, 281c, 281d, 281e of the second semiconductor structure 20 respectively correspond to the connectors 181a, 181b, 181c, 181d, and 181e of the first semiconductor structure 10. It should be noted that the example illustrated in FIG. 2A is not intended to be limiting, and the number, size, shape, and position of the connectors may vary depending on design requirements.

As illustrated in FIGS. 2A-2B, the first and second semiconductor structures 10 and 20 are bonded in a face-to-face manner to form a die stack structure 200B. For example, the first semiconductor structure 10 is turned upside down and mounted onto the second semiconductor structure 20. In detail, the front side (F) of the first semiconductor structure 10 and the front side (F′) of the second semiconductor structure 20 are bonded together at a bonding interface 182, and a bonding region 190 is formed across the bonding interface 182. The bonding interface 182 may be formed by adhesion and merger of the bonding layer 124 of the first semiconductor structure 10 and the bonding layer 224 of the second semiconductor structure 20. In some embodiments, if the first and second semiconductor structures 10 and 20 do not include the bonding layers 124 and 224, the bonding interface 182 is formed by the adhesion and merger of a portion of each of the third cover layers 123 and 223. In some embodiments, at least a portion of the respective cover layers of the first and second semiconductor structures (i.e., at least a portion of the first cover layers 121 and 221, at least a portion of the second cover layers 122 and 222, and/or at least a portion of the third cover layers 123 and 223) are included in the bonding region 190 and contribute to the bonding between the first and second semiconductor structures 10 and 20.

In some embodiments, before the first semiconductor structure 10 is bonded to the second semiconductor structure 20, the multiple connectors 181 and 281 are aligned in the Z-direction, such that the multiple pairs of connectors (e.g., connectors 181a and 281a, connectors 181b and 281b, connectors 181c and 281c, connectors 181d and 281d, and connectors 181e and 281e) are formed in a face-to-face manner. In some embodiments, the alignment of the multiple connectors 181 and 281 may be achieved by using an optical sensing method. After the alignment is achieved, the first and second semiconductor structures 10 and 20 are bonded together. As a result, multiple bonding structures 185 (e.g., bonding structures 185a, 185b, 185c, 185d, and 185e) are formed, respectively corresponding to the coupling of the pair of connectors 181a and 281a, the coupling of the pair of connectors 181b and 281b, the coupling of the pair of connectors 181c and 281c, the coupling of the pair of connectors 181d and 281d, and the coupling of the pair of connectors 181e and 281e. It is noted that at least one bonding structure 185 (e.g., bonding structure 185c) extends vertically through the bonding region 190 and interconnect the first test pad 112a of the first die 100 and the second test pad 212a of the second die 200.

In some embodiments, the bonding between the first and second semiconductor structures 10 and 20 of the die stack structure 200B is formed by hybrid bonding with application of pressure and heat. It is noted that the hybrid bonding involves at least two types of bonding, including metal-to-metal bonding and non-metal-to-non-metal bonding such as dielectric-to-dielectric bonding or fusion bonding. As an example shown in FIGS. 2A-2B, the bonding structures 185 are formed by metal-to-metal bonding, and the bonding layer 124 of the first semiconductor structure 10 and the bonding layer 224 of the second semiconductor structure 20 are bonded by non-metal-to-non-metal bonding.

It should be noted that the first and second probe marks 160 and 260 may be vertically aligned and in proximity to each other, and the bonding structure 185c is proximate to both the first and second probe marks 160 and 260. Regardless of the proximity, the risk for void and cracks induced by the probe marks 160 and 260 is significantly reduced, at least in part due to the multiple cover layers filled in both the first and second probe marks 160 and 260. As a result, the mechanical durability, reliability, and performance of the die stack structure 200B can be accordingly improved.

As illustrated in FIG. 2C, an insulating encapsulation 128 is formed aside the first die 100. In some embodiments, a material of the insulating encapsulation 128 includes a molding compound. The molding compound may include a resin and a filler. In some alternatively embodiments, a material of the insulating encapsulation 128 includes an oxide or a nitride, such as silicon oxide, silicon nitride, or a combination thereof. The insulating encapsulation 128 may be formed by spin-coating, lamination, deposition or the like. For example, the insulating encapsulation 128 may be formed by firstly forming an encapsulant material (not shown) over and covering the first die 100. Thereafter, the encapsulant material over the first die 100 is removed by a planarization process such as a CMP process. In some embodiments, a portion of the encapsulant material is removed so that a back side of the first die 100 is exposed after the planarization process. Thus, the back side of the first die 100 is substantially planar with a top surface of the insulating encapsulation 128.

After the insulating encapsulation 128 is formed, at least one first through-substrate via (TSV) 130 is formed. The TSV 130 penetrates the first semiconductor substrate 102 and is electrically connected with the first metal features 108 of the first interconnect structure 104. The TSV 130 is used to provide electrical connections between the first die 100 and the to-be-formed redistribution circuit structure 140. In some embodiments, the TSV 130 includes a conductive via. The conductive via is made of copper, copper alloys, aluminum, aluminum alloys, or combinations thereof. In some other embodiments, the TSV 130 further includes a diffusion barrier layer (not shown) surround the conductive via. The diffusion barrier layer is made of Ta, TaN, Ti, TiN, CoW or a combination thereof, and may be formed by a suitable process such as electro-chemical plating process, CVD, ALD, PVD or the like.

At least one through dielectric via (TDV) 132 is formed in the insulating encapsulation 128 to electrically connected with the second interconnect structure 204 and the to-be-formed redistribution circuit structure 140. In some embodiments, the TDV 132 includes a conductive via. The conductive via is made of copper, copper alloys, aluminum, aluminum alloys, or combinations thereof. In some other embodiments, the TDV 132 further includes a diffusion barrier layer (not shown) surround the conductive via. The diffusion barrier layer is made of Ta, TaN, Ti, TiN, CoW, or a combination thereof, and may be formed by a suitable process such as electro-chemical plating process, CVD, ALD, PVD, or the like.

After the TSV 130 and the TDV 132 are formed, a redistribution circuit structure 140 is formed over the back side of the first die 100 and over the insulating encapsulation 128. The redistribution circuit structure 140 includes multiple dielectric layers 140a and multiple redistribution conductive layers 140b stacked alternately. One portion of the redistribution conductive layers 140b is electrically connected with the TSV 130. Another portion of the redistribution conductive layers 140b is electrically connected with the TDV 132. Furthermore, the topmost redistribution conductive layer 140b includes at least one pad. In some embodiments, the above-mentioned pads include a plurality of bonding pads 140b1 for mounting conductive connectors (e.g., metal pillars, micro-bumps, or a combination thereof) bumps, and/or at least one test pad 140b2 for conducting a die backside performance test. The number of the bonding pads 140b1 and the test pads 140b2 is not limited in this disclosure. The material of the bonding pads 140b1 includes a metal or a metal alloy. The bonding pad 140b1 is, for example, aluminum, copper, nickel, or alloys thereof. The material of the test pad 140b2 may be the same as or different from that of the first and second test pads 112 and 212. In some embodiments, the test pad 140b2 includes a metal material, such as aluminum, copper, nickel, gold, silver, tungsten, or a combination thereof.

After a passivation layer 150 is formed over the redistribution circuit structure 140 and partially covers the bonding pads 140b1 and the test pads 140b2, a die stack structure 200C is accomplished. The passivation layer 150 includes silicon oxide, silicon nitride, benzocyclobutene (BCB) polymer, polyimide (PI), polybenzoxazole (PBO), or a combination thereof and is formed by a suitable process such as spin coating, CVD, or the like.

The die stack structure 200C may be further processed to form a package. For example, a singulation process may be performed to cut the die stack structure into individual chips. The individual chips may be mounted onto a substrate, which serves as a foundation for the finished package. The substrate may be made of a variety of materials, such as ceramic or plastic, depending on the specific requirements of the device. Once the chips are attached to the substrate, wires or other interconnects are used to connect the individual chips together and to other components on the substrate through wire bonding. The entire package may be encapsulated in a protective material, such as epoxy resin or plastic, to protect the delicate components from damage and environmental factors such as moisture or dust. The finished package may be tested to ensure that all of the components are functioning properly and that the package meets the required specifications.

FIG. 3 is a flowchart diagram illustrating an example method 300 of fabricating a semiconductor structure and a die stack structure in accordance with some embodiments. Cross-sectional views of the semiconductor structure and the die stack structure at various fabrication stages are illustrated in FIGS. 1A-1F and 2A-2C. Details of the semiconductor structure and the die stack structure formed at various fabrication stages have been described above and will not be repeated unless otherwise indicated.

In the illustrated example of FIG. 3, the method 300 includes operations 302, 304, 306, 308, 310, 312, and 314. Additional operations may be performed. Also, it should be understood that the sequence of the various operations discussed above with reference to FIG. 3 is provided for illustrative purposes, and as such, other embodiments may utilize different sequences. These various sequences of operations are to be included within the scope of embodiments.

At 302, a first cover layer is formed on a first test pad of a first die. The first test pad is disposed on a front side of the first die and has a first probe mark in an upper portion of the first test pad. At least a portion (e.g., an inner portion) of the probe mark is filled with the material of the first cover layer. At least a portion (i.e., an outer portion) of the probe mark may remain unfilled after forming the first cover layer. The first cover layer may be composed of a low-stress material such as low-stress oxide. At 304, a second cover layer is formed on the first cover layer. The second cover layer fills the unfilled portion of the probe mark. The second cover layer may include a high-stress material such as high-stress oxide. In at least one embodiment, a volume ratio of the first cover layer to the second cover layer (V/V) in the probe mark is at least 35:65. At 306, a third cover layer is formed on the second cover layer. The third cover layer may include a material that is the same as the first cover layer. The third cover layer may be a bonding layer used to form a bonding interface with another die to-be-stacked to the first die. One or more additional layers may be formed on the third cover layer. In some embodiments, only three cover layers are formed on the first test pad and no more bonding layer is formed on the third cover layer before the die bonding and stacking process.

At 308, a die stacking process is performed to bond the first die and another chip. In some embodiments, operation 308 further includes operations 310, 312, and 314. At 310, an opening on the top of the first test pad is formed. The opening is proximate to the first probe mark and extends vertically through the cover layers 123, 122, and 121 to expose a top surface of the first test pad. The opening is configured to receive and accommodate a connecting element (connector). In some embodiments, multiple openings are formed.

At 312, a connector is disposed in the opening. The connector may be a conductive element configured to be bonded to a connector of another die or chip. In some embodiments, the connector is a metal pad configured to form a metal-to-metal bonding with a metal pad of another die or chip. In some embodiments, the connector is a C4 bump or micro bump configured to bond to another die or chip. In some embodiments, multiple connectors are disposed respectively in the multiple openings.

At 314, the first die is bonded to another die or chip. In some embodiments, the die or chip to be bonded to the first die is a second die similar to the first die. In some embodiments, the second die includes a second test pad. The second test pad includes a second probe mark that is filled with a first material derived from the first cover layer formed on the second test pad and a second material derived from a second cover layer formed on the first test pad. Similar to the first die, the second die may also have a connector disposed in an opening proximate to the second probe mark. The connector is formed on the front side of the second die and in contact with the second test pad. The first die and the second die may be aligned such that the connectors of the first and second die are vertically aligned before die stacking. A bonding structure is formed when the two connectors from the first and second die are bonded through metal-to-metal bonding, and the bonding structure interconnects the first and the second test pad and is proximate to both the first and second probe mark. In some embodiments, the first and second die are bonded together through hybrid bonding.

### Summary

In accordance with some aspects of the disclosure, a semiconductor structure is provided. In one example, the semiconductor structure includes a die. The die has a test pad disposed on a front side of the die. The test pad has a probe mark in an upper portion of the test pad, the probe mark has an open end at a top surface of the test pad, a bottom wall, a sidewall connected to the bottom wall, and a space between the open end, the bottom wall and the sidewall. The semiconductor structure further includes a first cover layer disposed on the front side of the first test pad and on the sidewall and the bottom wall of the probe mark. The first cover layer fills a portion of the space and includes a first material. The semiconductor structure further includes a second cover layer disposed on the first cover layer. The second cover layer fills a second portion of the space and includes a second material different from the first material. In some embodiments, the semiconductor structure further includes a third cover layer disposed on the second cover layer. In some embodiments, the third cover layer includes a third material having a stress level less than the stress level of the second material.

In some embodiments, the first portion has a volume of at least 35%, and the second portion has a volume of at most 65%, based on a total volume of the space of the probe mark. In some embodiments, the first and second portions of the space are complementary.

In some embodiments, the first material has a first stress level, the second material has a second stress level higher than the first stress level. In some embodiments, the first stress level is from 130 MPa to 160 MPa, and the second stress level is from 170 MPa to 230 MPa.

In some embodiments, the first cover layer has a first thickness, the second cover layer has a second thickness greater than the first thickness. In some embodiments, the first thickness is from 0.3 μm to 0.7 μm.

In accordance with some aspects of the disclosure, a die stack structure is provided. In one example, a die stack structure includes a first semiconductor structure and a second semiconductor structure bonded together in a face-to-face manner at a bonding interface. The first semiconductor structure includes a first die having a first metal pad disposed on a front side of the first die. The first metal pad is a first test pad having a first probe mark in an upper portion of the first test pad. The first probe mark has an open end at a top surface of the first test pad, a bottom wall, a sidewall connected to the bottom wall, and a space between the open end, the bottom wall and the sidewall. The first semiconductor structure further includes a first cover layer, a second cover layer, and a third cover layer sequentially formed on the front side of the first test pad in a vertical direction. The first cover layer is disposed on the sidewall and the bottom wall of the probe mark. The first cover layer fills a first portion of the space and includes a first material. The second cover layer is disposed on the first cover layer, fills a second portion of the space, and includes a second material different from the first material. The third cover layer disposed on the second cover layer. The second semiconductor structure includes a second die having a second metal pad disposed on a front side of the second die. The second semiconductor structure further includes at least one cover layer disposed on the second test pad. The die stack structure further includes at least one bonding structure connecting the first metal pad and the second metal pad. The at least one bonding structure vertically extends through the first, second, and third cover layers of the first semiconductor structure, the bonding interface, and the at least one cover layer of the second semiconductor structure. The bonding structure is proximate to the first probe mark.

In accordance with some aspects of the disclosure, a method for fabricating a semiconductor structure is provided. In one example, the method includes providing a die. The die has a test pad disposed on the front side, the test pad has a probe mark in an upper portion of the test pad, the probe mark has an open end at a top surface of the test pad, a bottom wall, a sidewall connected to the bottom wall, and a space between the open end, the bottom wall and the sidewall. The method further includes forming a first cover layer on the front side of the first test pad such that the first cover layer fills a first portion of the space and leaves a second portion of the space unfilled. The first cover layer is disposed on the sidewall and the bottom wall of the probe mark and includes a first material having a first stress level. The method further includes forming a second cover layer on the first cover layer such that the second cover layer fills the second portion of the space. The second cover layer comprises a second material having a second stress level higher than the first stress level. In some embodiments, the method further includes forming a third cover layer on the second cover layer. The third cover layer is a bonding layer and includes a third material having a third stress level less than the second stress level.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor structure, comprising:
a die having a test pad disposed on a front side of the die, wherein the test pad has a probe mark in an upper portion of the test pad, the probe mark has an open end at a top surface of the test pad, a bottom wall, a sidewall connected to the bottom wall, and a space between the open end, the bottom wall and the sidewall;
a first cover layer disposed on the front side of the test pad and in the space, and on the sidewall and the bottom wall of the probe mark, and the first cover layer comprises a first material; and
a second cover layer disposed on the first cover layer and in the space, wherein the second cover layer comprises a second material different from the first material.

2. The semiconductor structure of claim 1, wherein the first cover layer fills a first portion of the space of the probe mark, the second cover layer fills a second portion of the space of the probe mark, the first portion is connected to the sidewall and bottom wall of the probe mark, and the second portion is complementary to the first portion.

3. The semiconductor structure of claim 1, wherein the first material has a first stress level, the second material has a second stress level higher than the first stress level.

4. The semiconductor structure of claim 3, wherein the first stress level is from 130 MPa to 160 MP, and the second stress level is from 170 MPa to 230 MPa.

5. The semiconductor structure of claim 2, wherein the first portion has a volume of at least 35%, and the second portion has a volume of at most 65%, based on a total volume of the space of the probe mark.

6. The semiconductor structure of claim 1, wherein the probe mark has a width and a height, wherein the width as measured by a horizontal dimension of the open end is from 12 μm to 16 μm, and the height as measured by a vertical distance from the open end to the bottom wall is from 0.5 μm to 0.8 μm.

7. The semiconductor structure of claim 1, wherein the first cover layer has a first thickness, the second cover layer has a second thickness greater than the first thickness.

8. The semiconductor structure of claim 7, wherein the first thickness is from 0.3 μm to 0.7 μm.

9. The semiconductor structure of claim 1, further comprising a third cover layer disposed on the second cover layer.

10. The semiconductor structure of claim 9, wherein the third cover layer comprises a third material having a stress level less than the stress level of the second material.

11. The semiconductor structure of claim 9, further comprising a bonding layer disposed on the third cover layer, the bonding layer configured to form a bonding interface with another die to be stacked onto the die.

12. The semiconductor structure of claim 1, further comprising a connector in contact with the test pad and extending through the first and second cover layer, the connector is proximate to the probe mark and configured to be connected to another die.

13. The semiconductor structure of claim 12, wherein the connector is configured to be connected to another test pad in another die.

14. The semiconductor structure of claim 13, wherein the connector is a micro-bump.

15. A die stack structure, comprising:
a first semiconductor structure and a second semiconductor structure bonded together in a face-to-face manner at a bonding interface, wherein the first semiconductor structure comprises:
a first die having a first metal pad disposed on a front side of the first die, wherein the first metal pad is a first test pad having a first probe mark in an upper portion of the first test pad, the first probe mark has an open end at a top surface of the first test pad, a bottom wall, a sidewall connected to the bottom wall, and a space between the open end, the bottom wall and the sidewall;
a first cover layer disposed on the front side of the first test pad and in the space, and on the sidewall and the bottom wall of the probe mark, and the first cover layer comprises a first material;
a second cover layer disposed on the first cover layer and in the space, wherein the second cover layer comprises a second material different from the first material; and
a third cover layer disposed on the second cover layer;
wherein the second semiconductor structure comprises:
a second die having a second metal pad disposed on a front side of the second die; and
at least one cover layer disposed on the second metal pad; and
at least one bonding structure connecting the first metal pad and the second metal pad, wherein the at least one bonding structure vertically extends through the first, second, and third cover layers of the first semiconductor structure, the bonding interface, and the at least one cover layer of the second semiconductor structure, and the at least one bonding structure is proximate to the first probe mark.

16. The die stack structure of claim 15, wherein,
the second metal pad is a second test pad having a second probe mark in an upper portion of the second test pad, wherein the bonding structure is proximate to the second probe mark; and
the at least one cover layer of the second semiconductor structure further comprises:
a fourth cover layer disposed on the front side of the second test pad, wherein the fourth cover layer comprises the first material;
a fifth cover layer disposed on the fourth cover layer, wherein the fifth fourth cover layer comprises the second material; and
a sixth cover layer disposed on the fifth cover layer, the sixth cover layer bonded to the third cover layer at the bonding interface.

17. The die stack structure of claim 16, wherein,
the first cover layer fills a first portion of the space of the first probe mark, the second cover layer fills a second portion of the space of the first probe mark, the first portion is connected to the sidewall and the bottom wall of the first probe mark, and the second portion is complementary to the first portion; and
the fourth cover layer fills a third portion of the space of the second probe mark, the fifth cover layer fills a fourth portion of the space of the second probe mark, the third portion is connected to [the] a sidewall and a bottom wall of the second probe mark, and the fourth portion is complementary to the third portion.

18. The die stack structure of claim 16, wherein the first material is a low-stress oxide having a first stress level from 130 MPa to 160 MPa, and the second material is a high-stress oxide having a second stress level from 170 MPa to 230 MPa.

19. A method for fabricating a semiconductor structure, comprising:
providing a die, wherein the die has a test pad disposed on a front side of the die, the test pad has a probe mark in an upper portion of the test pad, the probe mark has an open end at a top surface of the test pad, a bottom wall, a sidewall connected to the bottom wall, and a space between the open end, the bottom wall and the sidewall;
forming a first cover layer on the front side of the test pad and in the space, and on the sidewall and the bottom wall of the probe mark, and the first cover layer comprises a first material having a first stress level; and
forming a second cover layer on the first cover layer and in the space, wherein the second cover layer comprises a second material having a second stress level higher than the first stress level.

20. The method of claim 19, further comprising:
forming a third cover layer on the second cover layer, wherein the third cover layer is a bonding layer comprising a third material having a third stress level less than the second stress level.
